(19) United States
(12) Patent Application Publication
(10) Pub. No.: US 2026/0310063 A1
(43) Pub. Date: Oct. 8, 2026

(54) SYSTEM AND METHOD FOR 3D MASK MODEL BASED ON HUYGENS-FRESNEL PRINCIPLE

(71) Applicant: Samsung Electronics Co., Ltd., Gyeonggi-do (KR)

(72) Inventors: Xin ZHOU, San Jose, CA (US); Majd KUTEIFAN, San Jose, CA (US); Yumin WANG, San Jose, CA (US); Boshen GAO, San Jose, CA (US); Sagar TRIVEDI, San Jose, CA (US); Mindy R. LEE, San Jose, CA (US); Sorang JEON, Gyeonggi-do (KR); Heungsuk OH, Gyeonggi-do (KR)

(21) Appl. No.: 19/303,697

(22) Filed: Aug. 19, 2025

Related U.S. Application Data
(60) Provisional application No. 63/782,853, filed on Apr. 3, 2025.

(51) Int. Cl. G03F 1/36; G03F 7/00

(52) U.S. Cl. CPC G03F 1/36; G03F 7/70441

(57) ABSTRACT

A system and method are provided for an image-based mask model in optical proximity correction. A method includes obtaining a mask shape, determining a point spread function (PSF) of a two-dimensional spatial frequency based on a line spread function (LSF) of a one-dimensional spatial frequency having a magnitude substantially equal to a magnitude of the two-dimensional spatial frequency, applying the PSF to the mask shape to obtain a three-dimensional (3D) mask effect, generating an aerial image based on the at least one 3D mask effect, and generating a resist contour based on the aerial image.

### CROSS-REFERENCE TO RELATED APPLICATION

This application claims the priority benefit under 35 U.S.C. § 119 (e) of U.S. Provisional Application No. 63/782,853, filed on Apr. 3, 2025, the disclosure of which is incorporated by reference in its entirety as if fully set forth herein.

### INTRODUCTION

Optical Proximity Correction (OPC) is a mask-synthesis software tool employed in lithography to maintain and improve the fidelity of integrated circuit (IC) patterning. A three-dimensional (3D) mask model has become a critical component of OPC for advanced nodes in IC production, ensuring accurate representation and control of the lithography process.

### SUMMARY

According to an embodiment, a three-dimensional (3D) thick mask modeling approach is based on the Huygens-Fresnel principle and is implemented using image processing techniques. Because it is better suited for curvilinear mask shapes than other edge-based methods, this technology is also more amenable to graphics processing unit (GPU) implementation than competing solutions.

According to an embodiment, a 3D thick mask modeling method derives a set of spatial-domain Huygens filters from rigorous solutions of Maxwell's equations for line/space patterns. These filters are then convolved with the pixels of the mask image near its edges, producing an approximate near field scattering. Different polarizations of illumination are addressed by employing distinct filters.

Alternatively, the disclosed Huygens filters can be expressed in the frequency domain. In this case, the mask image is further processed and placed into properly indexed frequency-domain buffers.

The convolution result, which represents scattering by the thick mask topography, is then combined with the Kirchhoff thin mask result. Together, these outputs form the necessary input for the optical model of the projection lithography tool.

In extreme ultraviolet (EUV) applications, the dot product of the wavevector and the mask gradient, denoted k·g, is the dominant factor in selecting the appropriate Huygens filters.

In accordance with an embodiment, an OPC method is provided for photolithography in semiconductor technology. The method includes obtaining at least one mask shape; applying an image-based mask model for the photolithography to the at least one mask shape, wherein applying the image-based mask model comprises determining a point spread function (PSF) of a two-dimensional spatial frequency based on a line spread function (LSF) of a one-dimensional spatial frequency having a magnitude substantially equal to a magnitude of the two-dimensional spatial frequency; and applying the PSF to the at least one mask shape to obtain a three-dimensional (3D) mask effect; enerating, based on the 3D mask effect, an aerial image indicating a projected light pattern resulting from the photolithography; and generating, based on the aerial image, a resist contour indicating a resist pattern on a semiconductor wafer.

In accordance with another embodiment, an OPC method is provided for photolithography in semiconductor technology. The method includes obtaining at least one mask shape; applying an image-based mask model for the photolithography to the at least one mask shape, wherein applying the image-based mask model comprises at least one of convolving a point spread function (PSF) with a mask; or multiplying a PSF in a frequency domain with a mask in the frequency domain; and applying the PSF to the at least one mask shape to obtain a three-dimensional (3D) mask effect; generating, based on the 3D mask effect, an aerial image indicating a projected light pattern resulting from the photolithography; and generating, based on the aerial image, a resist contour indicating a resist pattern on a semiconductor wafer.

In accordance with another embodiment, a computer system configured to perform OPC for photolithography in semiconductor technology is provided. The computer system includes at least one processor; and memory that stores instructions, which when executed by the at least one processor, control the computer system to obtain at least one mask shape; apply an image-based mask model for the photolithography to the at least one mask shape, wherein the image-based mask model models 3D thick mask effects of curvilinear mask shapes based on a Huygens-Fresnel principle, and wherein to apply the image-based mask model comprises to: determine a point spread function (PSF) of a two-dimensional spatial frequency based on a line spread function (LSF) evaluated for a one-dimensional spatial frequency, wherein a magnitude of the one-dimensional spatial frequency is substantially equal to a magnitude of the two-dimensional spatial frequency; and apply the PSF to the at least one mask shape to obtain a three-dimensional (3D) mask effect; generate, based on the 3D mask effect, an aerial image indicating a projected light pattern resulting from the photolithography; and generate, based on the aerial image, a resist contour indicating a resist pattern on a semiconductor wafer.

### BRIEF DESCRIPTION OF THE DRAWINGS

The above and other aspects, features, and advantages of certain embodiments of the present disclosure will be more apparent from the following detailed description, taken in conjunction with the accompanying drawings, in which:

FIGS. 1A through 1C are examples of three-dimensional (3D) thick mask shapes to be fabricated with lithography;

FIG. 2A is an example of a 3D thick mask shape to be convolved with a point-spread function (PSF);

FIG. 2B is an example of a PSF to be convolved with the shape of FIG. 2A, according to an embodiment;

FIG. 2C is an example of a convolution of the shape of FIG. 2A with the PSF of FIG. 2B, according to an embodiment;

FIG. 3 illustrates a relationship between an example two-dimensional (2D) PSF and an example one-dimensional (1D) line-spread function (LSF), according to an embodiment;

FIG. 4 is an example of a computed LSF for an edge, according to an embodiment;

FIG. 5 is a flow diagram illustrating a method for optical proximity correction, according to an embodiment;

FIG. 6 is a flow diagram illustrating a method for applying the PSF to mask shapes via image processing techniques, according to an embodiment;

FIG. 7 is a flow diagram illustrating a method for applying an optical proximity correction model by representing 3D thick mask effects of curvilinear shapes based on a Huygens-Fresnel principle, according to an embodiment;

FIG. 8 is a flow diagram illustrating a method of constructing an LSF from the solution of Maxwell's equations for a half-plane geometry;

FIG. 9 is an example of a computed Huygens PSF for bright and dark sides of a given mask, according to an embodiment; and

FIG. 10 is a block diagram of an electronic device, according to an embodiment.

### DETAILED DESCRIPTION

In the following detailed description, numerous specific details are set forth in order to provide a thorough understanding of the disclosure. It will be understood, however, by those skilled in the art that the disclosed aspects may be practiced without these specific details. In other instances, well-known methods, procedures, components and circuits have not been described in detail in order not to obscure the subject matter disclosed herein.

Reference throughout this specification to “one embodiment” or “an embodiment” means that a particular feature, structure, or characteristic described in connection with the embodiment may be included in at least one embodiment disclosed herein. Thus, the appearances of the phrases “in one embodiment” or “in an embodiment” or “according to one embodiment” (or other phrases having similar import) in various places throughout this specification may not necessarily all be referring to the same embodiment. Furthermore, the particular features, structures or characteristics may be combined in any suitable manner in one or more embodiments. In this regard, as used herein, the word “exemplary” means “serving as an example, instance, or illustration.” Any embodiment described herein as “exemplary” is not to be construed as necessarily preferred or advantageous over other embodiments. Additionally, the particular features, structures, or characteristics may be combined in any suitable manner in one or more embodiments. Also, depending on the context of discussion herein, a singular term may include the corresponding plural forms and a plural term may include the corresponding singular form. Similarly, a hyphenated term (e.g., “two-dimensional,” “pre-determined,” “pixel-specific,” etc.) may be occasionally interchangeably used with a corresponding non-hyphenated version (e.g., “two dimensional,” “predetermined,” “pixel specific,” etc.), and a capitalized entry (e.g., “Counter Clock,” “Row Select,” “PIXOUT,” etc.) may be interchangeably used with a corresponding non-capitalized version (e.g., “counter clock,” “row select,” “pixout,” etc.). Such occasional interchangeable uses shall not be considered inconsistent with each other.

Also, depending on the context of discussion herein, a singular term may include the corresponding plural forms and a plural term may include the corresponding singular form. It is further noted that various figures (including component diagrams) shown and discussed herein are for illustrative purpose only, and are not drawn to scale. For example, the dimensions of some of the elements may be exaggerated relative to other elements for clarity. Further, if considered appropriate, reference numerals have been repeated among the figures to indicate corresponding and/or analogous elements.

The terminology used herein is for the purpose of describing some example embodiments only and is not intended to be limiting of the claimed subject matter. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

It will be understood that when an element or layer is referred to as being on, “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like numerals refer to like elements throughout. As used herein, the term “and/or” includes any and all combinations of one or more of the associated listed items.

The terms “first,” “second,” etc., as used herein, are used as labels for nouns that they precede, and do not imply any type of ordering (e.g., spatial, temporal, logical, etc.) unless explicitly defined as such. Furthermore, the same reference numerals may be used across two or more figures to refer to parts, components, blocks, circuits, units, or modules having the same or similar functionality. Such usage is, however, for simplicity of illustration and ease of discussion only; it does not imply that the construction or architectural details of such components or units are the same across all embodiments or such commonly-referenced parts/modules are the only way to implement some of the example embodiments disclosed herein.

Unless otherwise defined, all terms (including technical and scientific terms) used herein have the same meaning as commonly understood by one of ordinary skill in the art to which this subject matter belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

As used herein, the term “module” refers to any combination of software, firmware and/or hardware configured to provide the functionality described herein in connection with a module. For example, software may be embodied as a software package, code and/or instruction set or instructions, and the term “hardware,” as used in any implementation described herein, may include, for example, singly or in any combination, an assembly, hardwired circuitry, programmable circuitry, state machine circuitry, and/or firmware that stores instructions executed by programmable circuitry. The modules may, collectively or individually, be embodied as circuitry that forms part of a larger system, for example, but not limited to, an integrated circuit (IC), system on-a-chip (SoC), an assembly, and so forth.

A Huygens filter is defined as a point-spread function (PSF) that is directly constructed from the corresponding line-spread function (LSF), eliminating the need for a data-fitting step. A set of these Huygens filters (which may be referred to interchangeably herein as PSFs) is then integrated over curvilinear mask edges in a manner similar to using Green's functions in the solution of partial differential equations (PDEs).

In the case of EUV lithography, a simplification arises from the dominance of the dot product k·g, which represents the projection of the illumination wavevector direction (e.g., a unit vector in the direction of the incident wavevector) onto the normal direction of the mask edges. This k·g indexing scheme can also be applied to deep ultraviolet (DUV) lithography with minimal modifications.

Implementation is facilitated by a GPU-friendly software framework that relies heavily on pixel-based image-processing techniques, ensuring efficient and scalable computation.

An advantage of this approach is its mathematically consistent and accurate treatment of curvilinear mask shapes in the first-order effect of light diffraction by 3D mask edges. This method does not require data training over a large set of precomputed Maxwell solutions, unlike certain competing approaches.

Another benefit lies in the comprehensive handling of multiple source sectors, made possible by the k·g indexing scheme.

The method does not necessarily account for second-order effects arising from edge-edge interactions or acute corners in mask shapes. However, because these second-order effects are typically much weaker than the first-order effects, the impact of their omission on overall accuracy is generally minimal.

The advanced nodes of semiconductor chip manufacturing require ever-shrinking feature sizes patterned by lithography. To fully utilize the resolution capabilities of EUV and DUV optical scanners, curvilinear mask shapes may be adopted to print desired circuit designs. However, the combination of small dimensions and curvilinear edges introduces significant challenges in the mask modeling component of optical proximity correction (OPC) software, which should solve the inverse problem of determining optimal mask shapes for any given circuit design. For example, in OPC based on forward modeling, the OPC software can adjust (e.g., modify) characteristics of the thick mask until a forward optical model predicts that the resulting lithographic pattern will be sufficiently accurate.

According to an embodiment, a 3D thick mask modeling (e.g., forward modeling) method, based on the Huygens-Fresnel principle, is provided. For example, the method may implement a 3D thick mask model such as an image-based 3D thick mask model (i3DM). A premise is that the distinct 3D mask effect, beyond what is captured by the Kirchhoff thin mask, stems from diffraction at the mask edges. Each infinitesimal edge element acts as a source of scattered light in accordance with the Huygens-Fresnel principle, and the overall near field pattern emerges from the coherent superposition of all these contributions.

Thus, the disclosed 3D thick mask modeling method can describe how light passes through a physical mask within a lithographic scanner, thereby encoding pattern information from the physical mask in the light field (e.g., near field) that emerges from the physical mask. According to an embodiment, the 3D thick mask modeling method can simulate interactions of the light with the physical mask (e.g., diffraction and scattering at the physical mask edges) by approximating the Maxwell equations without the computational effort of fully solving them. When the resulting 3D thick mask model is combined with the Kirchhoff thin mask model, the complete mask near field is obtained for subsequent use in the projection optics component of the OPC model. Accordingly, this improved 3D thick mask modeling method can improve the overall OPC result.

According to an embodiment, a 3D thick mask modeling method may focus on edge elements, rather than on edges of finite length. In this framework, the Huygens filters can be interpreted as edge-element responses to impulses of incoming illumination, reflecting a linear systems approach.

Accordingly, it is possible to choose Huygens filters that exhibit circular symmetry, provided that suitable stencils are constructed to separate and combine the effects of the dark and bright regions on the mask.

Furthermore, a direct method to compute the edge-element response is presented, represented as a PSF, from a library of infinite-edge responses expressed as LSFs.

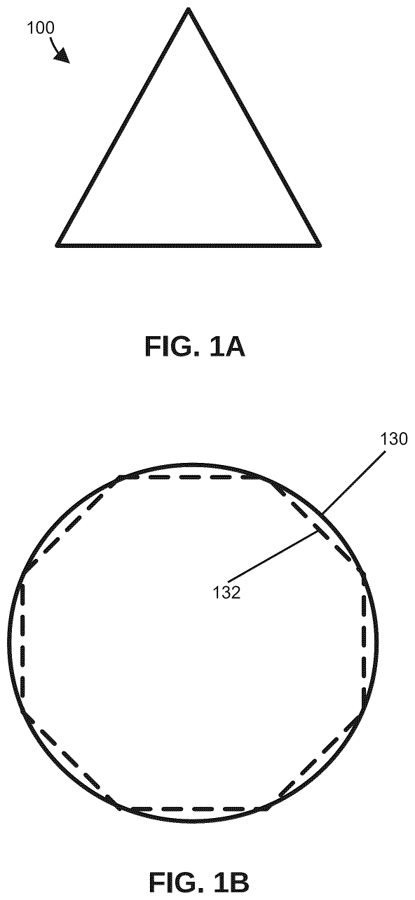

FIGS. 1A through 1C are examples of 2D orthographic projections of 3D thick mask shapes to be fabricated with lithography. The 2D orthographic projections of the shapes may necessarily be very curvilinear because of extremely small dimensions of patterns used in semiconductor technology, for example features with length scales of 10 nm to 100 nm. Accordingly, such curvilinear shapes may contain many small edge segments connecting multiple vertices. As a result, some OPC systems may run slowly and/or suffer reduced precision in determining the optimal mask shapes for the desired circuit designs.

In particular, some OPC systems may paste a 1D LSF (which may be retrieved from a library) directly onto an output buffer on the optical pixel grid. Such systems effectively approximate the 2D PSF by the 1D LSF, for example as G(kₓ, k_{y})≈F(kₓ). Therefore, such OPC systems are based on treating individual edge segments (such as the segments shown in the examples of FIGS. 1A through 1C) as infinite lines, which may be accurate for infinitely long line/space patterns. For Manhattan patterns (e.g., patterns having only vertical or horizontal edges), a further improvement by edge-coupling filter can be applied. However, for non-Manhattan patterns, the edge-coupling effect is difficult to consider. Accordingly, this approach of approximating the 2D PSFs by the 1D LSFs may be inaccurate, particularly for very short edges, as illustrated in the examples of FIGS. 1A through 1C. Since all operations are performed on the optical grid, the speed of such OPC systems may be satisfactory. However, such systems may also run slower for patterns with many small segments connecting vertices, as in FIGS. 1A through 1C.

Referring to FIG. 1A, a triangle 100 (e.g., an equilateral triangle) is an example of a shape with multiple edges, which may be poorly represented by treating the individual edge segments as infinite lines.

Likewise, referring to FIG. 1B, a circle 130, or another round shape such as an oval or ellipse, is an example of a curvilinear shape. The circle 130 may be approximated by a polygon, for example by an octagon 132. But this polygon in turn is poorly represented by treating its individual edge segments as infinite lines.

Referring to FIG. 1C, a trapezoid 160 is another example of a shape with multiple edges, which is also poorly represented by treating the shape as a collection of individual edge segments (e.g., represented as infinite lines). In this example, the incident photolithography light 162 (e.g., UV light) is modeled as illuminating the four edge segments of trapezoid 160. However, this model fails to include light scattering off the corners 164 of trapezoid 160, instead providing trapezoid 160 as a collection of individual edge segments, each of which is based on an infinite and isolated edge model.

Accordingly, for polygons and/or curvilinear shapes, such as those in the examples of FIGS. 1A through 1C, some OPC systems may perform slowly and/or suffer reduced precision. The disclosed system and methods can address these difficulties by determining a rotationally symmetric PSF (e.g., a Huygens filter) directly from an LSF and applying the PSF to a mask using image processing techniques, thereby providing a more accurate model of densely packed curvilinear patterns represented by extremely short edges and/or non-Manhattan patterns, while still providing a simple process to determine the PSF and apply it to the image mask.

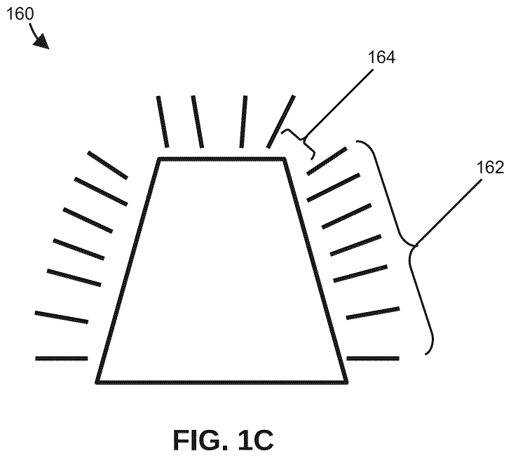

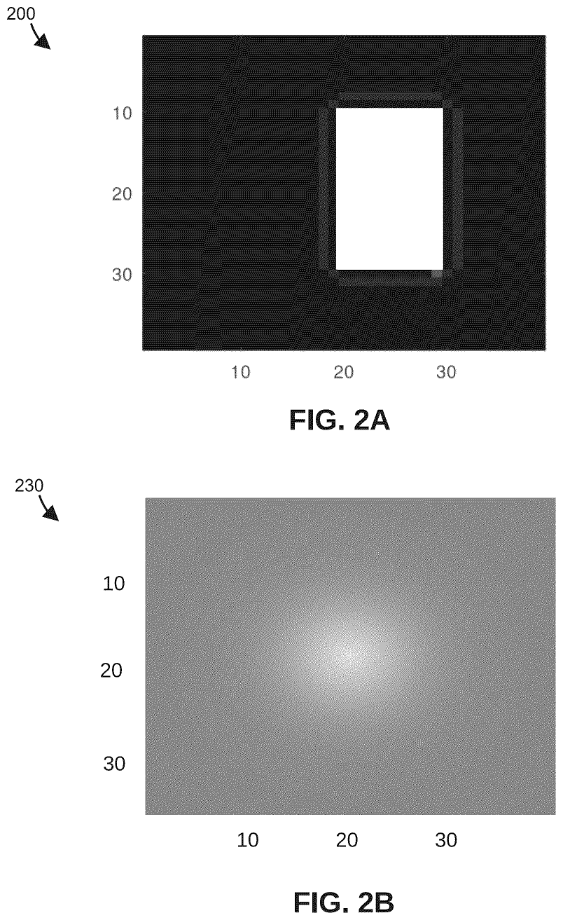

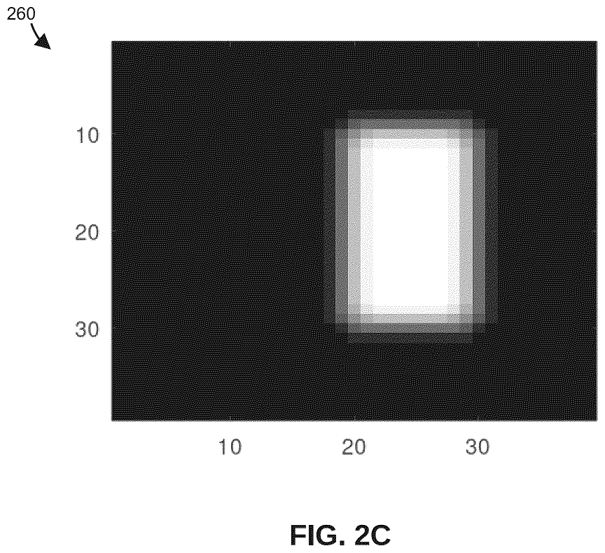

In particular, the disclosed system and methods can use image processing methods such as convolution to apply the PSF to the mask. FIGS. 2A through 2C illustrate a convolution of an example shape with an example PSF.

FIG. 2A is an example of a rectangle in a 3D thick mask shape 200. Referring to FIG. 2A, the 3D thick mask shape 200 has a rectangle with horizontal coordinates ranging between 20 and 30, and vertical coordinates between 10 and 30. Accordingly, in this example, the 3D thick mask shape 200 is a Manhattan pattern, since it has only horizontal and vertical edges. Moreover, the 3D thick mask shape 200 is a relatively simple Manhattan pattern, with just four edges. In other examples, the 3D thick mask shape 200 may be more complex, for example containing a plurality of shorter edges, as in FIGS. 1A through 1C.

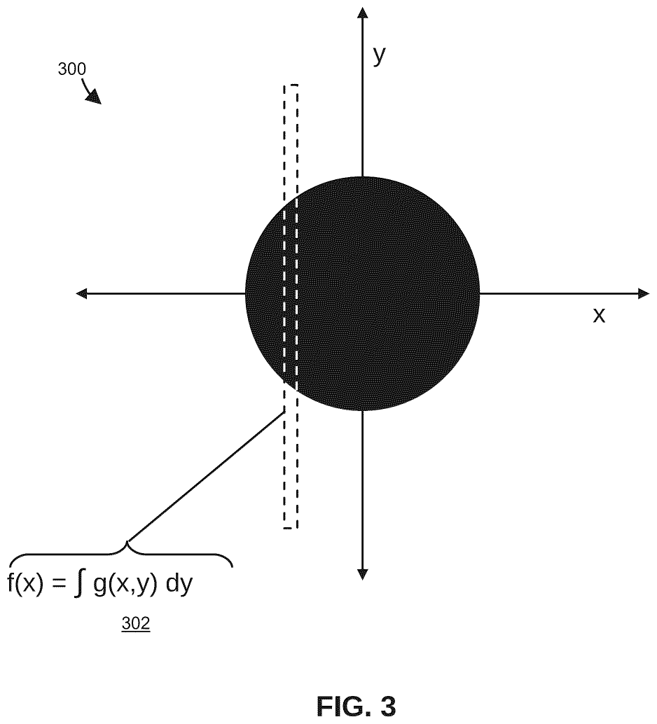

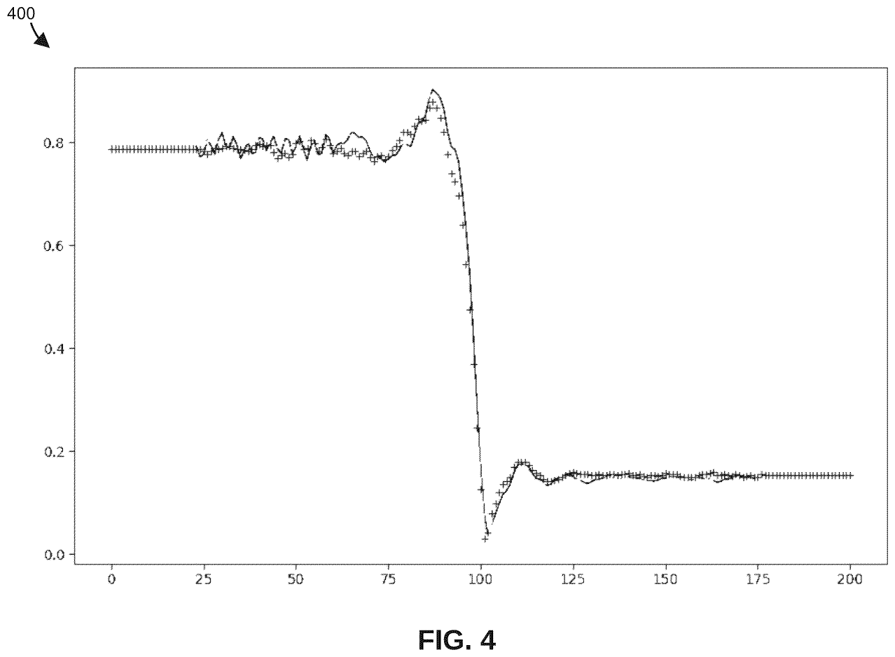

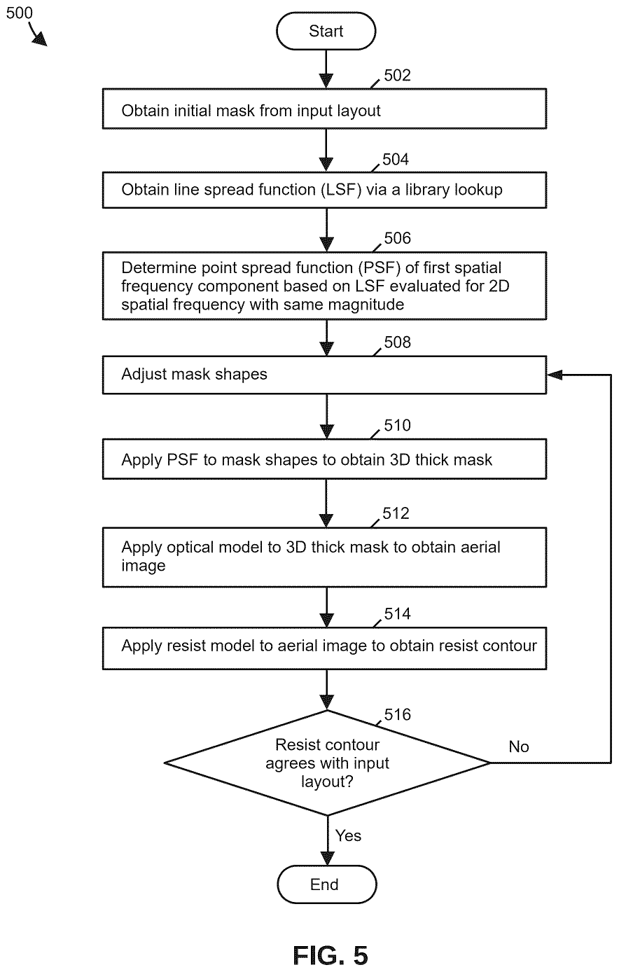

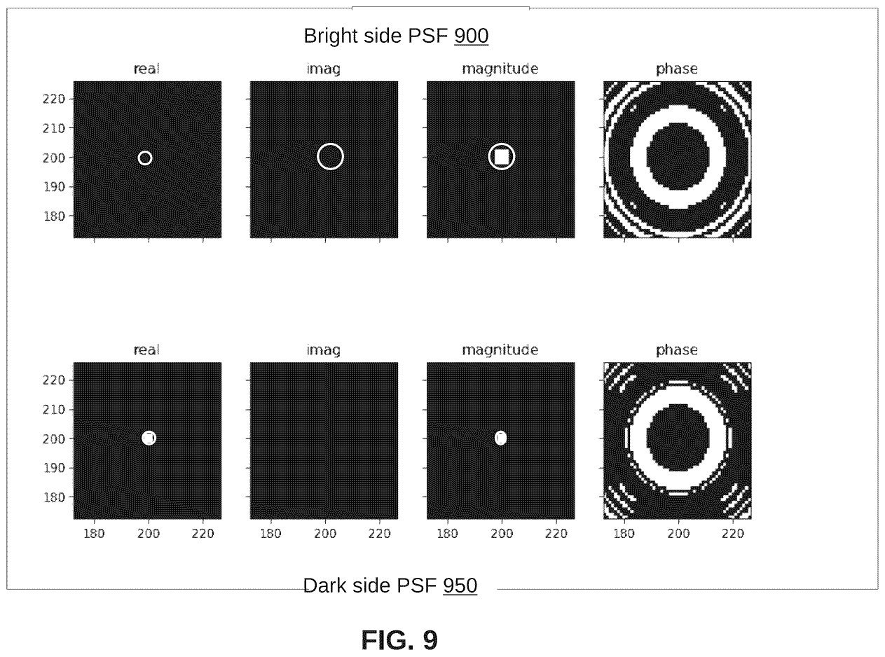

FIG. 2B is an example of a PSF 230 to be convolved with the rectangle of FIG. 2A, according to an embodiment. Referring to FIG. 2B, the PSF 230 possesses approximate circular symmetry, as shown. In an example, PSF 230 may correspond to the bright side PSF 900 or the dark side PSF 950 of the example of FIG. 9 below. Moreover, the PSF 230 may be determined from an LSF, such as the LSF of FIG. 4, according to the methods disclosed herein, for example in FIGS. 3 and 5.

FIG. 2C is an example of a convolution 260 of the rectangle of FIG. 2A with the PSF of FIG. 2B, according to an embodiment. As disclosed in greater detail herein, for example in FIGS. 3 and 5-7 below, the disclosed system and methods can apply the PSF to the mask by convolving the desired pattern with the appropriate PSFs. The appropriate PSFs can be chosen based on a slope, such as the dot product k·g, which represents the projection of the illumination wavevector direction onto the normal direction of the mask edges. Accordingly, the convolution 260 provides an example of an OPC model output for the given input 3D thick mask shape 200 and PSF 230.

Unlike the OPC systems that approximate the PSF as equal to the LSF, the disclosed system and methods can make use of a direct, exact relationship between a 2D PSF with rotational symmetry and the corresponding 1D LSF. The disclosed Huygens filters are PSFs directly constructed from the corresponding LSFs, without any need of a data-fitting step. FIG. 3 illustrates such a relationship between an example two-dimensional (2D) PSF 300, and an example one-dimensional (1D) LSF 302, according to an embodiment.

In particular, referring to FIG. 3, the PSF 300 possesses rotational symmetry, e.g. circular symmetry. It is possible to choose Huygens filters, such as PSF 300, that exhibit circular symmetry, provided that suitable stencils are constructed to separate and combine the effects of the dark and bright regions on the mask.

As shown, the LSF 302 ƒ(x) may be defined as an infinite line integral of the PSF 300, g(x, y):

$$f ( x ) = \int g ( x , y ) dy .$$

Equation 1

Accordingly, the disclosed system can determine the PSF from a corresponding LSF, which in turn can be obtained from a library of solutions of Maxwell equations, as described in the examples of FIGS. 4, 5, and 7 below.

Moreover, the disclosed system and methods can make use of an direct relationship between the Fourier transforms of the PSF and LSF, which states that the k_{y}=0 component of the Fourier transformed PSF G equals the Fourier transformed LSF F: G(kₓ, 0)=F(kₓ). A mathematical derivation of this relationship follows, based on the assumption that g is a 2D function with rotational symmetry. The derivation begins by integrating g over a straight line, as described in Equation 1 and FIG. 3, to produce the 1D line spread function ƒ. As in Equation 2 below, both sides of Equation 1 can be Fourier transformed, to yield the relationship between G and F:

$$f ( x ) = \int g ( x , y ) dy = \frac{1}{{( 2 π )}^{2}} \int \int \int G ( {k}_{x} , {k}_{y} ) {e}^{{jk}_{x} x} {e}^{{jk}_{y} y} {dk}_{x} {dk}_{y} dy = \frac{1}{2 π} \int \int G ( {k}_{x} , {k}_{y} ) {e}^{{jk}_{x} x} δ ( {k}_{y} ) {dk}_{x} {dk}_{y} = \frac{1}{2 π} \int G ( {k}_{x} , 0 ) {e}^{{jk}_{x} x} {dk}_{x} \qquad Equation 2$$

Therefore G(kₓ, 0)=F(kₓ) in the Fourier domain. Next, the derivation can make use of the rotational symmetry of G, as shown below in Equation 3.

$$G ( {k}_{x} , {k}_{y} ) = F ( \sqrt{{k}_{x}^{2} + {k}_{y}^{2}} ) \qquad Equation 3$$

Accordingly, the PSF G(kₓ, k_{y}) of an arbitrary two-dimensional spatial frequency is equal to the LSF

$$F ( \sqrt{{k}_{x}^{2} + {k}_{y}^{2}} ) ,$$

evaluated at a spatial frequency with a magnitude equal to the magnitude of the two-dimensional spatial frequency.

FIG. 4 is an example of a computed LSF 400 for an edge, according to an embodiment. Referring to FIG. 4, the plot shows LSF 400 as a 1D array of complex values. The LSF 400 in this example may be computed for a pattern having a very wide vertical space in the middle of an infinitely large background. Since the space width is large, each of the left and right edges can be considered a half-plane, with opposite polarity (e.g., rising vs falling). Accordingly, the LSF 400 shown in FIG. 4 can be considered as a magnified view of the right edge.

The near field may be largely determined by the incident angle of the photolithography illumination relative to the mask edge. For example, the EUV ripple may be dominated by the dot product k·g. Thus, in the case of EUV photolithography, a great simplification may be found in this dominance of k·g. Therefore, in some embodiments, when the LSF 400 is stored in a library of Maxwell solutions, the LSF 400 may be indexed by the dot product k·g. This k·g indexing scheme can be applied to DUV as well with minimal augmentation.

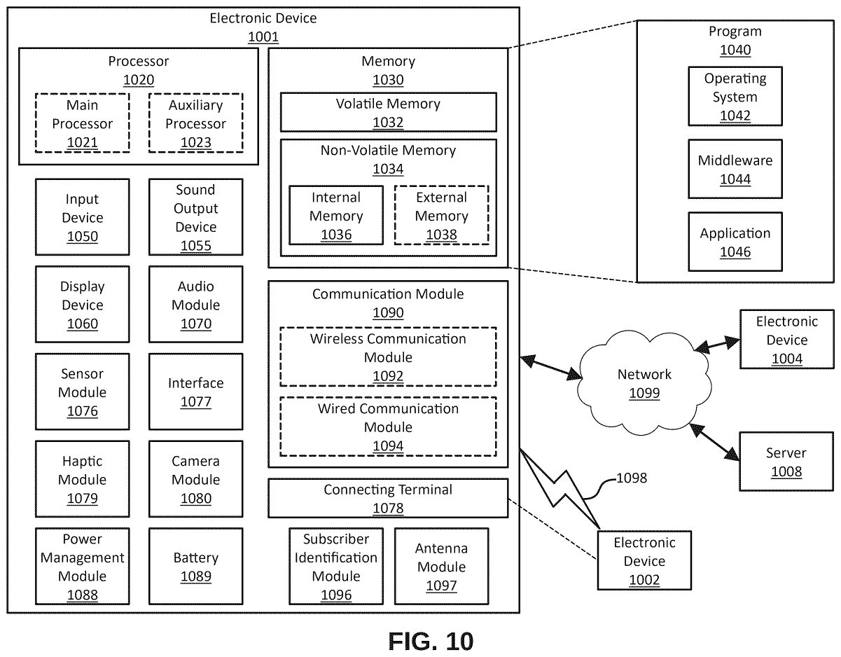

When LSFs for many example mask geometries have been computed and stored in a library, the disclosed system and methods can use them to determine Huygens filters (e.g., PSFs), which can then be convolved with thick mask patterns to perform OPC, according to the Huygens-Fresnel principle. FIG. 5 is a flow diagram illustrating such a method 500 for optical proximity correction, according to an embodiment. In some examples, the method 500 can be performed by an electronic device such as the electronic device 1001 of FIG. 10. The method 500 may be a forward-modeling OPC method, which proceeds by adjusting (e.g., modifying) the thick mask until the forward optical model predicts that the resulting lithographic pattern will be sufficiently accurate. The disclosed forward modeling method based on Huygens filters can improve over other models, such as edge-based models, thereby improving the overall OPC result.

Referring to FIG. 5, the method 500 can begin with the system obtaining at 502 an initial mask guess, for example from an input layout. For instance, the initial mask guess may represent an initial guess of the mask (e.g., mask shapes), prior to being corrected with OPC, according to an embodiment. Accordingly, the system can initialize the mask shapes to the initial mask guess obtained at 502. In one example, the input layout may be the same as the desired final pattern, but is not limited by the present disclosure.

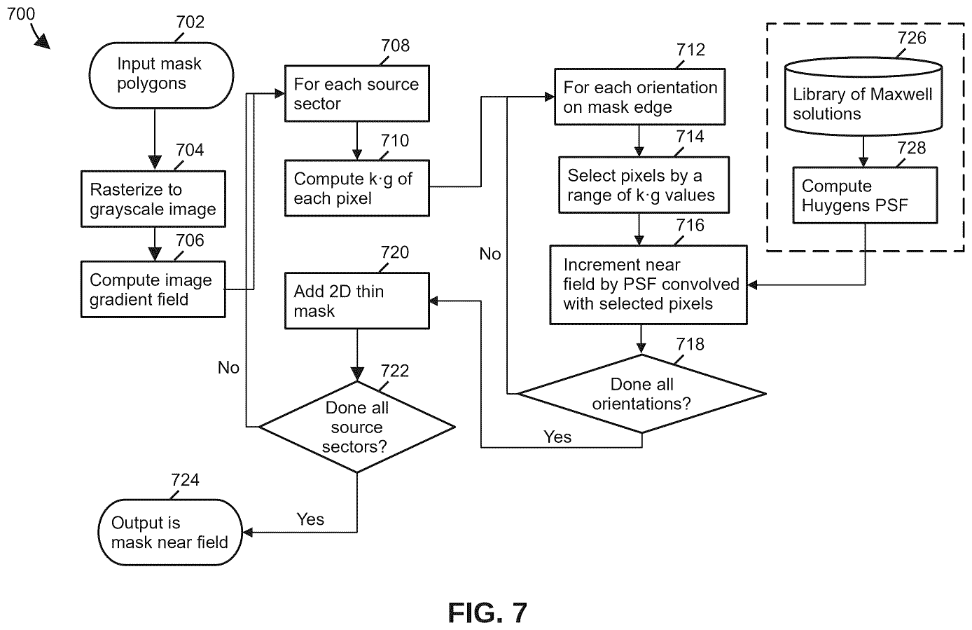

Next, the system can obtain at 504 an LSF via a library lookup. The lookup may be based on a slope, such as the dot product kg, which represents the projection of the illumination wavevector direction onto the normal direction of the mask edges, as described in greater detail in the example of FIG. 7 below. For example, the LSF obtained via the library lookup may have been previously computed by solving Maxwell's equations numerically via Finite Difference Time Domain (FDTD), Rigorous Coupled-Wave Analysis (RCWA), and/or another numerical method.

Next, the system can determine at 506 a point spread function (PSF) of a first spatial frequency component based on the obtained LSF evaluated for a 2D spatial frequency with the same magnitude as the magnitude of the first spatial frequency component. For example, as described in the example of FIG. 3, the PSF G(kₓ, k_{y}) can be evaluated for the two-dimensional spatial frequency (kₓ, k_{y}) and the LSF

$$F ( \sqrt{{k}_{x}^{2} + {k}_{y}^{2}} )$$

can be evaluated for the first spatial frequency component k₁≡\sqrt{kₓ²+k_{y}²}, which has a magnitude equal to the magnitude of the two-dimensional spatial frequency.

In some examples, the PSF is represented as a 2D matrix. Therefore, so as to conserve storage space and reduce lookup time, in some embodiments, the system may not store the entire set of PSFs in a library. Instead, since the LSF is a 1D array, and thus small enough to be stored in a library for all input parameters, the system may obtain at 504 the LSF via a library lookup, as described above. Accordingly, the system can compute at 506 the PSF as needed from the LSF and the dot product k·g.

Next, the system can adjust at 508 the mask shapes. For example, the system may iteratively shift characteristics of the mask pattern, such as edges, corners, and/or features of the mask. The system may adjust at 508 these characteristics of the mask shapes independently or together.

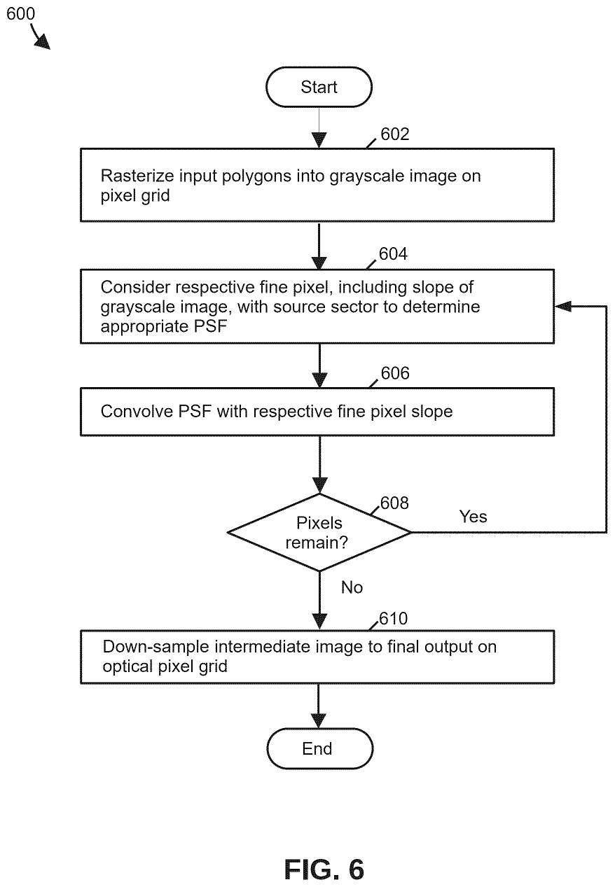

Next, the system can apply at 510 the determined PSF to the mask shapes to obtain a 3D thick mask model, such as an image-based 3D thick mask model (i3DM). For example, the system can use image processing techniques to apply at 510 the determined PSF to the mask shapes, as described in greater detail in FIG. 6 below.

The obtained 3D thick mask model may describe how light passes through a physical mask in the lithographic scanner setup, so as to encode the pattern information from the physical mask in the light field (e.g., near field). The disclosed 3D thick mask model can simulate the interactions of the light with the physical mask (such as diffraction and scattering) by approximating the effects of the Maxwell equations without the computational effort of fully solving the equations.

Next, the system can apply at 512 an optical model to the 3D thick mask model obtained at 510, to obtain an aerial image. For example, the aerial image may be a simulation of a resulting projected optical pattern arriving at the semiconductor wafer (e.g., at a photoresist layer on the wafer), in response to photolithography using the mask shapes. The simulation may be based on the 3D thick mask model obtained at 510.

Next, the system can apply at 514 a resist (e.g., photoresist) model to the aerial image to obtain a simulated resist contour. For example, the resist contour may be a simulation of photoresist patterns and/or etched structures formed on a wafer in response to lithography using the mask shapes.

Next, the system can compare at 516 the simulated resist contour to the input layout. If the resist contour does not agree with the input layout, the system can then return to re-adjust at 508 the mask shapes. For instance, the system may determine if the resist contour agrees with the input layout based on comparison to within a convergence tolerance.

If the resist contour does agree with the input layout to within the convergence tolerance, the system can make use of the OPC result as the final mask. The method 500 can then end.

FIG. 6 is a flow diagram illustrating a method 600 for applying the PSF to mask shapes via image processing techniques, according to an embodiment. For example, the method in FIG. 6 may illustrate additional details of the operation at 510 of method 500. The method in FIG. 6 may make use of a convolution of the PSFs with pixels representing the 3D thick mask, analogous to the use of Green's functions to solve partial differential equations (PDEs). In some examples, the method in FIG. 6 can be performed by an electronic device such as the electronic device 1001 of FIG. 10.

Referring to FIG. 6, the method can begin with the system rasterizing at 602 the input polygons into a grayscale image on a fine pixel grid. For example, polygons such as those in the examples of FIGS. 1A through 1C may be input, and may be rasterized into the grayscale image on the fine pixel grid. Each fine pixel can also store the slope of the grayscale image. For example, each fine pixel may store g, which represents the normal direction of the mask edges, and/or the dot product k·g, which represents the projection of the illumination wavevector direction k onto the normal direction g of the mask edges. In some examples, the mask edge normal direction g may be stored as the slope of the grayscale image, for example as the gradient of the grayscale image.

In an embodiment, rasterizing at 602 the polygons into a grayscale image can be one way the disclosed system and methods make use of image processing methods, which may be more efficient and better-suited to curvilinear mask shapes than edge geometry approaches. By rasterizing at 602 the polygons into a grayscale image, the disclosed system and methods may be suited to performing OPC based on the edge elements, rather than the edges of finite lengths. In addition, the disclosed image processing methods for applying the PSF may be more amenable to GPU implementation than other methods. In particular, pixel-based image processing, as in FIG. 6, may be better suited to GPU implementation than approaches that rely on retrieving look-up tables indexed by edge geometry.

Next, the system can consider at 604 a respective fine pixel, including the slope of the grayscale image, with the source sector to determine an appropriate PSF. For example, the PSFs may be determined from an LSF, as described in the examples of FIGS. 3 and 5 above. The LSF, in turn, may be stored in a library and indexed by the slope information, such as the dot product k·g. Accordingly, the system may determine at 604 the appropriate PSF by comparing the slope of the grayscale image with the index of the corresponding LSF. In some examples, different polarizations of illumination can be addressed by employing distinct PSFs.

Next, the system can convolve at 606 the PSF with the respective fine pixel slope. In some examples, if multiple pixels correspond to the same PSF, the multiple pixels can be convolved at 606 with that PSF. For example, the system can select multiple pixels by a range of k·g values, and then convolve the PSF with the selected pixels, as described in the example of FIG. 7 below. In some cases, the multiple pixels corresponding to the same PSF may be neighboring pixels.

An example convolution is illustrated in FIG. 2C. The Huygens filters can be considered edge element responses to the impulses of input illumination in the sense of linear systems, therefore the convolution at 606 can provide the 3D thick mask response to the entire set of selected pixels. Note that the use of convolution at 606 may be a core technique of standard digital image processing, but many existing OPC systems are unable to deploy convolution successfully for modeling 3D mask effects. Accordingly, by deploying image processing techniques such as convolution 606, the disclosed system and methods can improve on OPC technology, in particular because image processing techniques are fast and simple to apply.

According to an embodiment, the 3D thick mask modeling method makes extensive use of image processing methods, which are inherently well-suited to curvilinear mask shapes. In contrast, other edge-based approaches work best for Manhattan mask shapes that feature well-defined edge lengths and relatively few edge orientations. In addition, the disclosed method is also more compatible with GPU implementation than other methods, primarily because pixel-based image processing is better suited to GPUs than approaches that rely on retrieving look-up tables indexed by edge geometry.

In some examples, the system can make use of the convolution theorem to implement convolving at 606 the PSF with the respective fine pixel slope in the Fourier domain via multiplication. Accordingly, the methods in FIGS. 5 and 6 can be implemented even more efficiently.

Next, the system can determine at 608 whether additional pixels remain. If additional pixels remain, the system can return to operation at 604 to consider the next fine pixel.

Next, if no additional pixels remaining, the system can down-sample at 610 the intermediate image to a final output on the optical pixel grid. The method of FIG. 6 can then end.

FIG. 7 is a flow diagram illustrating a method 700 for applying an OPC model by representing 3D thick mask effects of curvilinear shapes based on a Huygens-Fresnel principle, according to an embodiment. The 3D thick mask modeling method is provided to illustrate the sequence of steps involved in constructing and applying Huygens filters for thick mask modeling in OPC. In some examples, the method 700 can be performed by an electronic device such as the electronic device 1001 of FIG. 10.

Referring to FIG. 7, the method 700 can begin with the system receiving input mask polygons at 702. For example, polygons such as those in the examples of FIGS. 1A through 1C may be input.

Next, the system can rasterize at 704 the input mask polygons to a grayscale image on a fine pixel grid.

Next, the system can compute at 706 the image gradient field g, which may represent the normal direction of the mask edges. In some examples, the mask edge normal direction g may be stored as the slope of the grayscale image, for example as the gradient of the grayscale image. For example, if the input mask is rasterized at 704 onto a fine grid of grayscale pixels, the mask edge normal direction g may be determined by computing the gradient of the grayscale values on the grid.

Next, the system can initiate a repetition at 708 iterating over each source sector (e.g., over the direction k of the incident photolithography light). Accordingly, at 708 through 722, the system can iterate over the direction of the incident light, such as the illumination wavevector direction k. For example, the system may iterate over discretized values of k, which may be a 2D vector. In an example, each discretized value may correspond to a range of k values, such as the range between discretized values.

Next, the system can compute at 710 the dot product k·g of each pixel, which represents the projection of the illumination wavevector direction onto the normal direction of the mask edges. For example, the system may compute at 710 the dot product k·g based on the source sector k being considered in the repetition at 708 and the image gradient field g computed at 706.

Next, the system can initiate a repetition at 712 iterating over each orientation of the mask edge (e.g., relative to the direction k of the incident photolithography light). In an embodiment, the orientation can correspond to the normal direction g of the mask edges. For example, the system may iterate over discretized values of g, which may be a 2D vector. In an example, each discretized value may correspond to a range of g values, such as the range between discretized values.

Next, the system can select at 714 pixels by a range of k·g values. For example, for each orientation (e.g., normal direction g) being considered in the repetition at 712 and each illumination wavevector direction k being considered in the repetition at 708, the system can determine a corresponding range of the dot product k·g. In an embodiment where the fine pixels store the dot product k·g as the slope, the system can then select at 714 pixels that have a slope falling in the determined range. Alternatively or additionally, in an embodiment where the fine pixels store the normal direction g, the system can compute the dot product k·g with the given illumination wavevector direction k for each pixel, and select at 714 pixels that have k·g in the determined range.

Next, the system can increment at 716 the near field by the PSF convolved with the selected pixels. The system can compute at 728 the Huygens PSF based on an LSF stored in a library 726 of Maxwell solutions, as described in the examples of FIGS. 3 and 5 above. In some examples, the library 726 of Maxwell solutions may include Maxwell solutions computed numerically via FDTD, RCWA, and/or another numerical method. In some examples, since the PSF is represented as a 2D matrix, the system may not store the entire set of PSFs in a library. Instead, a respective LSF can be represented as a 1D array, e.g. with less data than a corresponding PSF. Accordingly, the system may store the LSFs in the library 726 as functions of all input parameters, and can compute the corresponding PSFs from the LSFs as needed.

In some embodiments, the library 726 may store the LSFs indexed by the dot product k·g for which they are computed. For example, the LSF 400 of the example of FIG. 4 may be computed for an infinitely steep edge, e.g. the right edge of a wide vertical space in an infinitely large background, as described above. Because the near field is largely determined by the incident angle relative to the edge (e.g., the EUV ripple is dominated by the dot product k·g), the LSF 400 may be indexed by the dot product k·g. In this case, the system may determine the appropriate LSF based on a lookup in the library 726 for the index k·g corresponding to the k·g value of the current selected pixels. In some examples, different polarizations of illumination can be addressed by employing distinct LSFs and/or PSFs. After looking up and retrieving the appropriate LSF, the system may convert the LSF to a PSF, as described in the examples of FIGS. 3 and 5.

The system can then convolve the PSF with the selected pixels, as described in the examples of FIG. 2C and FIG. 6 above, and then increment at 716 the near field accordingly. In some examples, the system can make use of the convolution theorem to implement convolving the PSF with the selected pixels in the Fourier domain via multiplication. Accordingly, incrementing at 716 the near field can be performed even more efficiently.

Next, the system can determine at 718 if all orientations have been completed. If all orientations are not completed, the system can return to operation 712 for the next orientation.

If all orientations are completed, the system can then add at 720 a 2D thin mask. For example, the system can combine the convolution result (e.g., the result of the convolution at 716 iterated over all the orientations at 712), which represents scattering by the thick mask topography, with a Kirchhoff thin mask result. Accordingly, the combined result can provide the complete mask near field for the current source sector at 708.

Next, the system can determine at 722 if all source sectors are completed. If all source sectors are not completed, the system can return to operation 708 for the next source sector.

If all source sectors are completed, the system can output the mask near field at 724. In some embodiments, the output mask near field at 724 can provide the complete mask near field, including both the thick and thin mask results, iterated over all the source sectors at 708. Accordingly, the combined output mask near field at 724 can form the input for subsequent use in an optical model of the projection lithography tool (e.g., a projection optics component of the OPC model). The method 700 can then end.

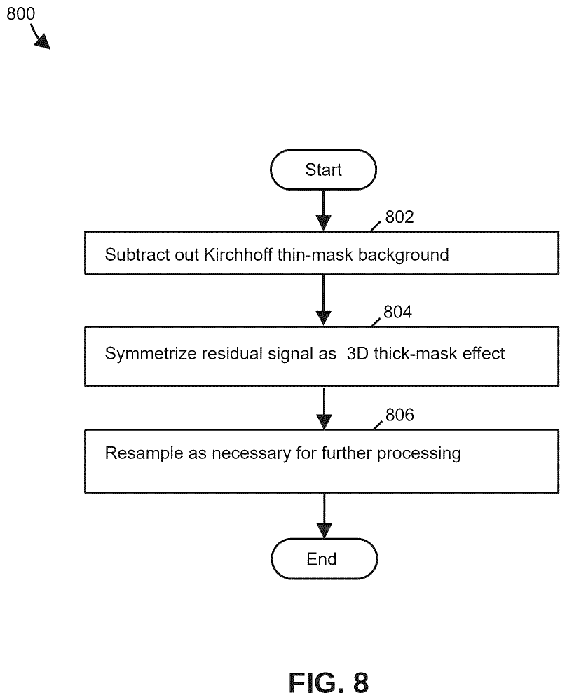

In addition, FIG. 8 is a flow diagram illustrating a method 800 of constructing an LSF from the solution of Maxwell's equations for a half-plane geometry. Referring to FIG. 8, the method 800 involves subtracting out the Kirchhoff thin-mask background at 802, symmetrizing the residual signal as a 3D thick-mask effect at 804, and then resampling as necessary for further processing at 806.

FIG. 9 is an example of a computed Huygens PSF for bright 900 and dark 950 sides of a given mask, according to an embodiment.

Referring to FIG. 9, the computed Huygens PSFs for the bright side 900 and dark side 950 of a given mask stack illustrate how these filters capture the scattering behavior of the mask edges. The bright and dark sides of a mask edge correspond to the inside and outside of the respective circuit design shapes. In the example of FIG. 4 (e.g., a half-plane or wide space mask), the bright side of the mask material stack may be where illumination light is transmitted or reflected with minimal loss, and mapped to bright regions on the wafer. Likewise, the dark side may be where the light is absorbed and mapped to dark regions on wafer. Since the bright region scatters light off the edges, such that the light travels outside the mask material stack, while for the dark side the light travels inside the mask stack, their corresponding Huygens filters 900 and 950 can be very different, as illustrated in this example.

For example, the bright side 900 can have a negative real part, while the dark side 950 has a positive real part. Both the bright side 900 and dark side 950 may have a negative imaginary part, but the imaginary part of the dark side 950 may be closer to zero. As shown, both bright side 900 and dark side 950 may have a similar magnitude, while their phases may alternate in circularly symmetric, but different, rings. In another example, the magnitude of bright side 900 and dark side 950 may differ as well, as the response of bright side 900 may be stronger than that of dark side 950.

FIG. 10 is a block diagram of an electronic device, according to an embodiment.

Referring to FIG. 10, an electronic device 1001 in a network environment 1000 may communicate with an electronic device 1002 via a first network 1098 (e.g., a short-range wireless communication network), or an electronic device 1004 or a server 1008 via a second network 1099 (e.g., a long-range wireless communication network). The electronic device 1001 may communicate with the electronic device 1004 via the server 1008. The electronic device 1001 may include a processor 1020, a memory 1030, an input device 1050, a sound output device 1055, a display device 1060, an audio module 1070, a sensor module 1076, an interface 1077, a haptic module 1079, a camera module 1080, a power management module 1088, a battery 1089, a communication module 1090, a subscriber identification module (SIM) card 1096, or an antenna module 1097. In one embodiment, at least one (e.g., the display device 1060 or the camera module 1080) of the components may be omitted from the electronic device 1001, or one or more other components may be added to the electronic device 1001. Some of the components may be implemented as a single integrated circuit (IC). For example, the sensor module 1076 (e.g., a fingerprint sensor, an iris sensor, or an illuminance sensor) may be embedded in the display device 1060 (e.g., a display).

The processor 1020 may execute software (e.g., a program 1040) to control at least one other component (e.g., a hardware or a software component) of the electronic device 1001 coupled with the processor 1020 and may perform various data processing or computations, e.g., the operations illustrated in FIGS. 5-7.

As at least part of the data processing or computations, the processor 1020 may load a command or data received from another component (e.g., the sensor module 1076 or the communication module 1090) in volatile memory 1032, process the command or the data stored in the volatile memory 1032, and store resulting data in non-volatile memory 1034. The processor 1020 may include a main processor 1021 (e.g., a central processing unit (CPU) or an application processor (AP)), and an auxiliary processor 1023 (e.g., a graphics processing unit (GPU), an image signal processor (ISP), a sensor hub processor, or a communication processor (CP)) that is operable independently from, or in conjunction with, the main processor 1021. Additionally or alternatively, the auxiliary processor 1023 may be adapted to consume less power than the main processor 1021, or execute a particular function. The auxiliary processor 1023 may be implemented as being separate from, or a part of, the main processor 1021.

The auxiliary processor 1023 may control at least some of the functions or states related to at least one component (e.g., the display device 1060, the sensor module 1076, or the communication module 1090) among the components of the electronic device 1001, instead of the main processor 1021 while the main processor 1021 is in an inactive (e.g., sleep) state, or together with the main processor 1021 while the main processor 1021 is in an active state (e.g., executing an application). The auxiliary processor 1023 (e.g., an image signal processor or a communication processor) may be implemented as part of another component (e.g., the camera module 1080 or the communication module 1090) functionally related to the auxiliary processor 1023.

The memory 1030 may store various data used by at least one component (e.g., the processor 1020 or the sensor module 1076) of the electronic device 1001. The various data may include, for example, software (e.g., the program 1040) and input data or output data for a command related thereto. The memory 1030 may include the volatile memory 1032 or the non-volatile memory 1034. Non-volatile memory 1034 may include internal memory 1036 and/or external memory 1038.

The program 1040 may be stored in the memory 1030 as software, and may include, for example, an operating system (OS) 1042, middleware 1044, or an application 1046.

The input device 1050 may receive a command or data to be used by another component (e.g., the processor 1020) of the electronic device 1001, from the outside (e.g., a user) of the electronic device 1001. The input device 1050 may include, for example, a microphone, a mouse, or a keyboard.

The sound output device 1055 may output sound signals to the outside of the electronic device 1001. The sound output device 1055 may include, for example, a speaker or a receiver. The speaker may be used for general purposes, such as playing multimedia or recording, and the receiver may be used for receiving an incoming call. The receiver may be implemented as being separate from, or a part of, the speaker.

The display device 1060 may visually provide information to the outside (e.g., a user) of the electronic device 1001. The display device 1060 may include, for example, a display, a hologram device, or a projector and control circuitry to control a corresponding one of the display, hologram device, and projector. The display device 1060 may include touch circuitry adapted to detect a touch, or sensor circuitry (e.g., a pressure sensor) adapted to measure the intensity of force incurred by the touch.

The audio module 1070 may convert a sound into an electrical signal and vice versa. The audio module 1070 may obtain the sound via the input device 1050 or output the sound via the sound output device 1055 or a headphone of an external electronic device 1002 directly (e.g., wired) or wirelessly coupled with the electronic device 1001.

The sensor module 1076 may detect an operational state (e.g., power or temperature) of the electronic device 1001 or an environmental state (e.g., a state of a user) external to the electronic device 1001, and then generate an electrical signal or data value corresponding to the detected state. The sensor module 1076 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 1077 may support one or more specified protocols to be used for the electronic device 1001 to be coupled with the external electronic device 1002 directly (e.g., wired) or wirelessly. The interface 1077 may include, for example, a high-definition multimedia interface (HDMI), a universal serial bus (USB) interface, a secure digital (SD) card interface, or an audio interface.

A connecting terminal 1078 may include a connector via which the electronic device 1001 may be physically connected with the external electronic device 1002. The connecting terminal 1078 may include, for example, an HDMI connector, a USB connector, an SD card connector, or an audio connector (e.g., a headphone connector).

The haptic module 1079 may convert an electrical signal into a mechanical stimulus (e.g., a vibration or a movement) or an electrical stimulus which may be recognized by a user via tactile sensation or kinesthetic sensation. The haptic module 1079 may include, for example, a motor, a piezoelectric element, or an electrical stimulator.

The camera module 1080 may capture a still image or moving images. The camera module 1080 may include one or more lenses, image sensors, image signal processors, or flashes. The power management module 1088 may manage power supplied to the electronic device 1001. The power management module 1088 may be implemented as at least part of, for example, a power management integrated circuit (PMIC).

The battery 1089 may supply power to at least one component of the electronic device 1001. The battery 1089 may include, for example, a primary cell which is not rechargeable, a secondary cell which is rechargeable, or a fuel cell.

The communication module 1090 may support establishing a direct (e.g., wired) communication channel or a wireless communication channel between the electronic device 1001 and the external electronic device (e.g., the electronic device 1002, the electronic device 1004, or the server 1008) and performing communication via the established communication channel. The communication module 1090 may include one or more communication processors that are operable independently from the processor 1020 (e.g., the AP) and supports a direct (e.g., wired) communication or a wireless communication. The communication module 1090 may include a wireless communication module 1092 (e.g., a cellular communication module, a short-range wireless communication module, or a global navigation satellite system (GNSS) communication module) or a wired communication module 1094 (e.g., a local area network (LAN) communication module or a power line communication (PLC) module). A corresponding one of these communication modules may communicate with the external electronic device via the first network 1098 (e.g., a short-range communication network, such as BLUETOOTH™, wireless-fidelity (Wi-Fi) direct, or a standard of the Infrared Data Association (IrDA)) or the second network 1099 (e.g., a long-range communication network, such as a cellular network, the Internet, or a computer network (e.g., LAN or wide area network (WAN)). These various types of communication modules may be implemented as a single component (e.g., a single IC), or may be implemented as multiple components (e.g., multiple ICs) that are separate from each other. The wireless communication module 1092 may identify and authenticate the electronic device 1001 in a communication network, such as the first network 1098 or the second network 1099, using subscriber information (e.g., international mobile subscriber identity (IMSI)) stored in the subscriber identification module 1096.

The antenna module 1097 may transmit or receive a signal or power to or from the outside (e.g., the external electronic device) of the electronic device 1001. The antenna module 1097 may include one or more antennas, and, therefrom, at least one antenna appropriate for a communication scheme used in the communication network, such as the first network 1098 or the second network 1099, may be selected, for example, by the communication module 1090 (e.g., the wireless communication module 1092). The signal or the power may then be transmitted or received between the communication module 1090 and the external electronic device via the selected at least one antenna.

Commands or data may be transmitted or received between the electronic device 1001 and the external electronic device 1004 via the server 1008 coupled with the second network 1099. Each of the electronic devices 1002 and 1004 may be a device of a same type as, or a different type, from the electronic device 1001. All or some of operations to be executed at the electronic device 1001 may be executed at one or more of the external electronic devices 1002, 1004, or 1008. For example, if the electronic device 1001 should perform a function or a service automatically, or in response to a request from a user or another device, the electronic device 1001, instead of, or in addition to, executing the function or the service, may request the one or more external electronic devices to perform at least part of the function or the service. The one or more external electronic devices receiving the request may perform the at least part of the function or the service requested, or an additional function or an additional service related to the request and transfer an outcome of the performing to the electronic device 1001. The electronic device 1001 may provide the outcome, with or without further processing of the outcome, as at least part of a reply to the request. To that end, a cloud computing, distributed computing, or client-server computing technology may be used, for example.

Embodiments of the subject matter and the operations described in this specification may be implemented in digital electronic circuitry, or in computer software, firmware, or hardware, including the structures disclosed in this specification and their structural equivalents, or in combinations of one or more of them. Embodiments of the subject matter described in this specification may be implemented as one or more computer programs, i.e., one or more modules of computer-program instructions, encoded on computer-storage medium for execution by, or to control the operation of data-processing apparatus. Alternatively or additionally, the program instructions can be encoded on an artificially generated propagated signal, e.g., a machine-generated electrical, optical, or electromagnetic signal, which is generated to encode information for transmission to suitable receiver apparatus for execution by a data processing apparatus. A computer-storage medium can be, or be included in, a computer-readable storage device, a computer-readable storage substrate, a random or serial-access memory array or device, or a combination thereof. Moreover, while a computer-storage medium is not a propagated signal, a computer-storage medium may be a source or destination of computer-program instructions encoded in an artificially generated propagated signal. The computer-storage medium can also be, or be included in, one or more separate physical components or media (e.g., multiple CDs, disks, or other storage devices). Additionally, the operations described in this specification may be implemented as operations performed by a data-processing apparatus on data stored on one or more computer-readable storage devices or received from other sources.

While this specification may contain many specific implementation details, the implementation details should not be construed as limitations on the scope of any claimed subject matter, but rather be construed as descriptions of features specific to particular embodiments. Certain features that are described in this specification in the context of separate embodiments may also be implemented in combination in a single embodiment. Conversely, various features that are described in the context of a single embodiment may also be implemented in multiple embodiments separately or in any suitable subcombination. Moreover, although features may be described above as acting in certain combinations and even initially claimed as such, one or more features from a claimed combination may in some cases be excised from the combination, and the claimed combination may be directed to a subcombination or variation of a subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the embodiments described above should not be understood as requiring such separation in all embodiments, and it should be understood that the described program components and systems can generally be integrated together in a single software product or packaged into multiple software products.

Thus, particular embodiments of the subject matter have been described herein. Other embodiments are within the scope of the following claims. In some cases, the actions set forth in the claims may be performed in a different order and still achieve desirable results. Additionally, the processes depicted in the accompanying figures do not necessarily require the particular order shown, or sequential order, to achieve desirable results. In certain implementations, multitasking and parallel processing may be advantageous.

As will be recognized by those skilled in the art, the innovative concepts described herein may be modified and varied over a wide range of applications. Accordingly, the scope of claimed subject matter should not be limited to any of the specific exemplary teachings discussed above, but is instead defined by the following claims.

What is claimed is:

1. An optical proximity correction (OPC) method for photolithography in semiconductor technology, the method comprising:
obtaining at least one mask shape;
applying an image-based mask model for the photolithography to the at least one mask shape, wherein applying the image-based mask model comprises:
determining a point spread function (PSF) of a two-dimensional spatial frequency based on a line spread function (LSF) of a one-dimensional spatial frequency having a magnitude substantially equal to a magnitude of the two-dimensional spatial frequency; and
applying the PSF to the at least one mask shape to obtain a three-dimensional (3D) mask effect;
generating, based on the 3D mask effect, an aerial image indicating a projected light pattern resulting from the photolithography; and
generating, based on the aerial image, a resist contour indicating a resist pattern on a semiconductor wafer.

2. The OPC method of claim 1, wherein:
the two-dimensional spatial frequency comprises a component along a first dimension and a component along a second dimension;
the component along the first dimension has a magnitude substantially equal to the magnitude of the one-dimensional spatial frequency; and
the component along the second dimension substantially equals zero.

3. The OPC method of claim 1, wherein the PSF possesses circular symmetry.

4. The OPC method of claim 1, further comprising constructing the LSF by solving Maxwell equations for a half plane pattern geometry.

5. The OPC method of claim 4, wherein constructing the LSF further comprises removing a Kirchhoff thin mask background, symmetrizing a residual signal as a 3D thick mask effect, and optionally resampling for further processing.

6. The OPC method of claim 4, wherein solving the Maxwell equations comprises applying a Finite Difference Time Domain (FDTD) method, a Rigorous Coupled-Wave Analysis (RCWA) method, or another numerical method.

7. The OPC method of claim 1, wherein the image-based mask model models 3D thick mask effects of curvilinear mask shapes based on a Huygens-Fresnel principle.

8. The OPC method of claim 1, wherein applying the PSF to the at least one mask shape to obtain the at least one 3D mask effect is based on image processing techniques.

9. The OPC method of claim 1, further comprising:
obtaining the LSF via a library lookup; and
applying the PSF to a mask.

10. The OPC method of claim 9, wherein the library is indexed by a relative orientation between:
a normal direction g of a respective curvilinear edge element of the mask; and
a source wavevector k.

11. The OPC method of claim 9, wherein:
a respective polygon of the mask is rasterized into a respective grayscale image on a pixel grid;
a respective pixel of the pixel grid stores a respective slope of the respective grayscale image; and
looking up the LSF is based at least in part on the respective slope of the respective grayscale image.

12. An optical proximity correction (OPC) method for photolithography in semiconductor technology, the method comprising:
obtaining at least one mask shape;
applying an image-based mask model for the photolithography to the at least one mask shape, wherein applying the image-based mask model comprises:
at least one of:
convolving a point spread function (PSF) with a mask; or
multiplying a PSF in a frequency domain with a mask in the frequency domain; and
applying the PSF to the at least one mask shape to obtain a three-dimensional (3D) mask effect;
generating, based on the 3D mask effect, an aerial image indicating a projected light pattern resulting from the photolithography; and
generating, based on the aerial image, a resist contour indicating a resist pattern on a semiconductor wafer.

13. The OPC method of claim 12, wherein:
the PSF in the frequency domain comprises a Fourier transform of the PSF; or
the mask in the frequency domain comprises a Fourier transform of the mask.

14. The OPC method of claim 12, further comprising:
determining the PSF or the PSF in the frequency domain based on a line spread function (LSF) or an LSF in the frequency domain.

15. The OPC method of claim 14, wherein determining the PSF or the PSF in the frequency domain based on the LSF or the LSF in the frequency domain comprises:
solving Maxwell equations for a half plane pattern geometry;
constructing the LSF in the frequency domain based on the solved Maxwell equations; and
determining the PSF in the frequency domain for a two-dimensional spatial frequency based on the LSF in the frequency domain for a one-dimensional spatial frequency, wherein a magnitude of the one-dimensional spatial frequency is substantially equal to a magnitude of the two-dimensional spatial frequency.

16. The OPC method of claim 12, wherein the image-based mask model models 3D thick mask effects of curvilinear mask shapes based on a Huygens-Fresnel principle.

17. A computer system configured to perform optical proximity correction (OPC) for photolithography in semiconductor technology, the computer system comprising:
at least one processor; and
memory that stores instructions, which when executed by the at least one processor, control the computer system to:
obtain at least one mask shape;
apply an image-based mask model for the photolithography to the at least one mask shape, wherein the image-based mask model models 3D thick mask effects of curvilinear mask shapes based on a Huygens-Fresnel principle, and wherein to apply the image-based mask model comprises to:
determine a point spread function (PSF) of a two-dimensional spatial frequency based on a line spread function (LSF) evaluated for a one-dimensional spatial frequency, wherein a magnitude of the one-dimensional spatial frequency is substantially equal to a magnitude of the two-dimensional spatial frequency; and
apply the PSF to the at least one mask shape to obtain a three-dimensional (3D) mask effect;
generate, based on the 3D mask effect, an aerial image indicating a projected light pattern resulting from the photolithography; and
generate, based on the aerial image, a resist contour indicating a resist pattern on a semiconductor wafer.

18. The computer system of claim 17, wherein the instructions further control the computer system to construct the LSF from a solution of Maxwell equations for a half plane pattern geometry.

19. The computer system of claim 18, wherein the solution of the Maxwell equations comprises a Finite Difference Time Domain (FDTD) solution, a Rigorous Coupled-Wave Analysis (RCWA) solution, or another numerical solution.

20. The computer system of claim 17, wherein:
the instructions further control the computer system to obtain the LSF via a library lookup; and
to apply the PSF to the at least one mask shape to obtain the at least one 3D mask effect comprises to apply, using image processing techniques, the PSF to the at least one mask shape to obtain the at least one 3D mask effect.
